(19) United States
(12) Patent Application Publication
(10) Pub. No.: US 2011/0147764 A1
(43) Pub. Date: Jun. 23, 2011

(54) TRANSISTORS WITH A DIELECTRIC CHANNEL DEPLETION LAYER AND RELATED FABRICATION METHODS

(75) Inventors: Sarit Dhar, Cary, NC (US); Sei-Hyung Ryu, Cary, NC (US); Veena Misra, Apex, NC (US); Daniel J. Lichtenwalner, Raleigh, NC (US)

(73) Assignees: Cree, Inc.; North Carolina State University

(21) Appl. No.: 12/612,499

(22) Filed: Nov. 4, 2009

Related U.S. Application Data
(60) Provisional application No. 61/237,401, filed on Aug. 27, 2009.

(51) Int. Cl. H01L 29/78; H01L 21/28; H01L 21/265

(52) U.S. Cl. 257/77; 438/585; 438/522; 257/E29.255; 257/E21.207; 257/E21.336

(57) ABSTRACT

A metal-insulator-semiconductor field-effect transistor (MISFET) includes a semiconductor layer with source and drain regions of a first conductivity type spaced apart therein. A channel region of a first conductivity type extends between the source and drain regions. A gate contact is on the channel region. A dielectric channel depletion layer is between the gate contact and the channel region. The dielectric channel depletion layer provides a net charge having the same polarity as the first conductivity type charge carriers, and which may deplete the first conductivity type charge carriers from an adjacent portion of the channel region when no voltage is applied to the gate contact.

### CROSS REFERENCE TO RELATED APPLICATIONS

The present application claims the benefit of and priority to U.S. Provisional Patent Application No. 61/237,401, filed Aug. 27, 2009, the disclosure of which is hereby incorporated by reference in its entirety.

### STATEMENT OF GOVERNMENT INTEREST

The present invention was made with support from the Department of the Army, contract number W911NF-04-2-0022. The Government has certain rights in this invention.

### FIELD OF THE INVENTION

The present invention relates to microelectronic devices and more particularly to transistors, for example, metal-insulator-semiconductor field-effect transistors (MISFETs) and related fabrication processes.

### BACKGROUND

Power semiconductor devices are widely used to regulate large current, high voltage, and/or high frequency signals. Modern power devices are generally fabricated from monocrystalline silicon semiconductor material. One widely used power device is the power Metal Oxide Semiconductor Field Effect Transistor (MOSFET). In a power MOSFET, a control signal is supplied to a gate electrode that is separated from the semiconductor surface by an intervening silicon dioxide insulator. Current conduction occurs via transport of majority carriers, without the presence of minority carrier injection that is used in bipolar transistor operation.

MOSFETS can be formed on a silicon carbide (SiC) layer. Silicon carbide (SiC) has a combination of electrical and physical properties that make it attractive as a semiconductor material for high temperature, high voltage, high frequency and/or high power electronic circuits. These properties include a 3.0 eV bandgap, a 4 MV/cm electric field breakdown, a 4.9 W/cm-K thermal conductivity, and a 2.0×107 cm/s electron drift velocity.

Consequently, these properties may allow silicon carbide-based MOSFET power devices to operate at higher temperatures, higher power levels, higher frequencies (e.g., radio, S band, X band), and/or with lower specific on-resistance than silicon-based MOSFET power devices. A power MOSFET fabricated in silicon carbide is described in U.S. Pat. No. 5,506,421 to Palmour entitled “Power MOSFET in Silicon Carbide” and assigned to the assignee of the present invention.

Increasing the electron mobility of silicon carbide-based MOSFETs may improve their power and frequency operational characteristics. Electron mobility is the measurement of how rapidly an electron is accelerated to its saturated velocity in the presence of an electric field. Semiconductor materials which have a high electron mobility are typically preferred because more current can be developed with a lower field, resulting in faster response times when a field is applied.

### SUMMARY

In accordance with some embodiments, a metal-insulator-semiconductor field-effect transistor (MISFET) includes a semiconductor layer with source and drain regions of a first conductivity type spaced apart therein. A channel region of the first conductivity type extends between the source and drain regions. A gate contact is on the channel region. A dielectric channel depletion layer is between the gate contact and the channel region. The dielectric channel depletion layer provides a net charge having the same polarity as the first conductivity type charge carriers.

The dielectric channel depletion layer may deplete the first conductivity type charge carriers from an adjacent portion of the channel region, which may allow the dopant concentration and/or thickness of the channel region to be increased so as to increase the electron mobility of the channel region while also enabling the MISFET to turn off with a very low drain leakage current when the gate contact voltage is less than a threshold voltage. The dielectric channel depletion layer may alternatively or additionally raise the threshold value of the MISFET (e.g., increase to a higher positive voltage).

In some other embodiments, a MISFET includes a n+ source region and a n+ drain region spaced apart in a silicon carbide SiC layer. A n-type channel region extends between the source and drain regions. A gate contact is on the channel region. An Al₂O₃ layer is between the gate contact and the channel region and provides a net negative charge that depletes the first conductivity type charge carriers from at least an adjacent portion of the channel region when the voltage potential between the gate contact and the source region is zero.

In some other embodiments, a method of fabricating a MISFET includes providing spaced apart source and drain regions of a first conductivity type in a semiconductor layer. First conductivity type impurity atoms are implanted to form a channel region between the spaced apart source and drain regions. A dielectric channel depletion layer is formed on the channel region. A gate contact is formed on the dielectric channel depletion layer over the channel region. The dielectric channel depletion layer provides a net charge having the same polarity as the first conductivity type charge carriers.

In some other embodiments, a MISFET includes a silicon carbide SiC layer having source and drain regions of a first conductivity type spaced apart therein. A gate contact is on a channel region of the SiC layer between the source and drain regions. A depletion layer is between the gate contact and the SiC layer. The depletion layer has a net charge that is the same polarity as the first conductivity type charge carriers.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1 is a cross-sectional view of a metal-insulator field-effect transistor (MISFET) with a dielectric channel depletion layer on a doped channel region in accordance with some embodiments of the present invention;

FIG. 2 is a cross-sectional view of a MISFET with an intervening insulation layer between a dielectric channel depletion layer and a doped channel region in accordance with some other embodiments of the present invention;

FIG. 3 is a cross-sectional view of the MISFET of FIG. 1 with a dielectric channel depletion layer that depletes and pinches-off the doped channel region when a zero voltage is present between a gate contact and a source region in accordance with some embodiments of the present invention;

FIG. 4 is a graph of a potential distribution that may occur with depth across the doped channel region of the MISFET of FIG. 3 and which illustrates that the channel region is depleted and pinched off while the gate voltage is below a threshold value;

FIG. 5 is a cross-sectional view of the MISFET of FIG. 1 with a threshold voltage applied between the gate contact and the source region to induce conduction through a narrow accumulation layer across the channel region and thereby cause a low current flow through a drain contact in accordance with some embodiments of the present invention;

FIG. 6 is a graph of a potential distribution that may occur with depth across the doped channel region of the MISFET of FIG. 5 and which illustrates that a narrow accumulation layer has formed across the channel region to allow low current flow through the drain contact;

FIG. 7 is a cross-sectional view of the MISFET of FIG. 1 with a voltage, which is substantially higher than the threshold voltage, that is applied between the gate contact and the source region to induce conduction through at least a majority of the channel region and cause a high current through the drain contact in accordance with some embodiments of the present invention;

FIG. 8 is a graph of a potential distribution that may occur with depth across the doped channel region of the MISFET of FIG. 7 and which illustrates that an accumulation layer has formed across the channel region to allow high current flow through the drain contact;

FIG. 9 is a graph of the drain current versus gate voltage operational characteristics that may be provided by the MISFET of FIG. 1; and

FIGS. 10-13 are a sequence of cross-sectional views of processes for fabricating the MISFET of FIG. 2 in accordance with some embodiments of the present invention; and

FIG. 14 is a cross-sectional view of a MISFET with a depletion layer on a channel region of a SiC layer in accordance with some embodiments of the present invention.

### DETAILED DESCRIPTION OF EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region. layer or section. and similarly, a second region, layer or section may be termed a first region, layer or section without departing from the teachings of the present invention.

Furthermore, relative terms, such as “lower” or “bottom” or “upper” or “top” or “lateral” or “vertical” may be used herein to describe one element's relationship to another elements as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

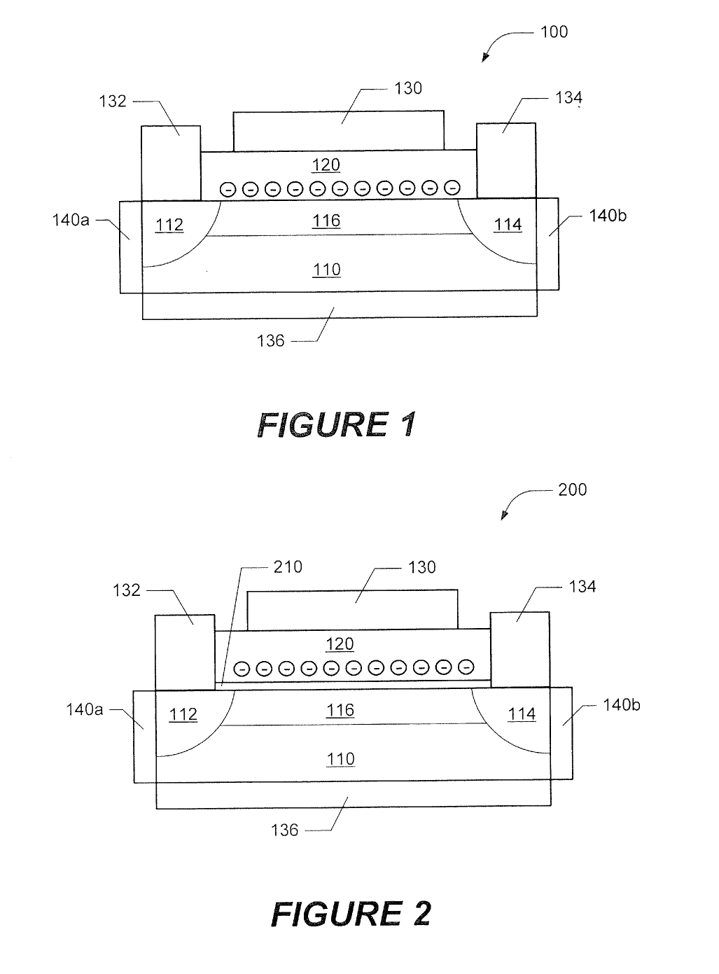

Various embodiments of the present invention are described in the context of increasing the electron mobility of channel regions in metal-insulator field-effect transistors (MISFETs). FIG. 1 is a cross-sectional view of a MISFET 100 that is configured in accordance with some embodiments of the present invention. Referring to FIG. 1, the MISFET 100 includes a semiconductor layer 110. The semiconductor layer 110 may be a high purity semi-insulating (HPSI) 4H-SiC substrate. SiC substrates are available from Cree Inc., Durham, NC. A n+ source region 112 and a n+drain region 114 are spaced apart in the semiconductor layer 110. A n-type channel region 116 extends between the source region 112 and the drain region 114. The presence of the n-type dopants in the channel region 116 can increase its electron mobility.

A gate contact 130 is aligned over the channel region 116 and may partially overlap the source region 112 and the drain region 114. A dielectric layer 120 separates the gate contact 130 from the semiconductor layer 110. A source contact 132 contacts the source region 112 and a drain contact 134 contacts the drain region 114. A body contact 136 is on an opposite surface of the semiconductor layer 110 from the gate contact 130. The source contact 132, the drain contact 134, and/or the body contact 136 may include nickel or another suitable metal. The MISFET 100 may be isolated from adjacent devices on the semiconductor layer 110 by isolation regions 140a-b (e.g., shallow trench isolation regions).

The electron mobility of the channel region 116 may be increased by increasing its dopant concentration and/or increasing the channel thickness (vertical direction in FIG. 2), which can decrease the channel resistance and correspondingly increase the channel current capacity. However, the level of increase in electron mobility that can be achieved through channel doping and/or increasing thickness of the channel region 116 can be constrained by a requirement for the MISFET 100 to turn off with a very low (preferably zero) drain leakage current when the voltage potential between the gate contact 130 and the source region 112 (V_{GS}) is less than a defined threshold voltage.

Some embodiments of the present invention may arise from the present realization that the MISFET 100 may be fabricated with improved operational characteristics by configuring the dielectric layer 120 to provide, along a surface facing the channel region 116, a net fixed charge (e.g., the negative charge symbols in FIG. 1) that has the same polarity as the majority charge carriers (e.g., electrons) in the channel region 116, and which, thereby, depletes the majority charge carriers (e.g., electrons) from at least an adjacent portion of the channel region 116 when the gate to source voltage V_{GS} is zero.

Because the fixed charge in the dielectric layer 120 (referred to as a dielectric channel depletion layer 120) forces charge carriers away from the adjacent channel region 116, the channel region 116 may be fabricated to have a higher n-type dopant concentration and/or to have a greater thickness so as to provide higher mobility in the channel region 116 and/or to provide increased channel current capacity while allowing the MISFET 100 to turn off when V_{GS} is less than the threshold voltage. The dielectric channel depletion layer 120 may alternatively or additionally be used to increase the threshold voltage of the MISFET 100 via the net fixed charge in the dielectric channel depletion layer 120 depleting charge carriers from the adjacent channel region 116.

The dielectric channel depletion layer 120 may be formed from a material, such as Al₂O₃ or HfO₂, that provides a fixed negative charge that depletes electrons by forcing them away from at least an adjacent portion of the n-type channel region 116 for V_{GS} less than the threshold voltage. For example, a layer of Al₂O₃ may be used as the dielectric channel depletion layer 120 to provide a negative fixed charge density of −6×10¹² cm Using a layer of Al₂O₃ as the dielectric channel depletion layer 120 may also reduce leakage current between the channel region 116 and the gate contact 130 because of the higher band gap difference (band offset) between the Al₂O₃ layer 120 and the SiC n-type channel region 116 compared to using another dielectric material having a negative fixed charge, such as HfO₂, having a lower band gap than Al₂O₃.

The choice of material and thickness of the dielectric channel depletion layer 120 should be selected to generate a net charge per unit area that is at least as high as a net charge generated by dopants in an adjacent unit area of the channel region 116. Thus, for example, a product of the doping concentration and thickness of the channel region 116 should be equal to or less than the amount of negative fixed charge provided by the dielectric channel depletion layer 120, as defined by the following Equation 1:

N_channel X n_channel≦Ng. (Equation 1)

In Equation 1, the term “N channel” represents the n-type dopant concentration (e.g., cm⁻³) of the channel region 116, the term “n_channel” represents the thickness (e.g., cm) of the channel region 116, and the term “Ng” represents the negative fixed charge density (cm⁻²) provided by the dielectric channel depletion layer 120.

In some embodiments, the channel region 120 may have a n-type dopant concentration from about 1×10¹⁶ cm⁻³ to about 1×10¹⁸ cm⁻³ and a thickness from about 0.1 μm to about 0.5×10⁻⁵ μm. Thus, according to Equation 1, the material and thickness of the dielectric channel depletion layer 120 are configured to generate a net charge density that is in a range from about −1×10¹¹ cm⁻² to about −5×10¹³ cm⁻². The source and drain regions each have a n-type dopant concentration that is greater than the n-type dopant concentration of the channel region 116, and may, for example, have a n-type dopant concentration from about 1×10¹⁹ cm⁻³to about 1×10²¹ cm⁻³.

Some further embodiments of the present invention may arise from the realization that the leakage current between the channel region 116 and the gate contact 130 may be further reduced and/or that the electron mobility through the channel region 116 may be further increased by providing an intervening insulation layer between the dielectric channel depletion layer 120 and the channel region 116. FIG. 2 is a cross-sectional view of a MISFET 200 with an intervening insulation layer 210 between the dielectric channel depletion layer 120 and the channel region 116 in accordance with some embodiments of the present invention. The MISFET 200 of FIG. 2 has a similar structure to the MISFET 100 of FIG. 1, but with the addition of the intervening insulation layer 210.

Referring to FIG. 2, the intervening insulation layer 210 is provided between the dielectric channel depletion layer 120 and the channel region 116. The intervening insulation layer 210 should be very thin, such as less than 100 Å, so that the charge provided by the dielectric channel depletion layer 120 is closely located to the channel region 116 to enable depletion of charge carriers from a deeper region of the channel region 116.

The intervening insulation layer 210 may be formed from SiO₂, such as by thermally oxidizing the SiC layer 110 either before or after the n-type channel region 116 is formed, and/or it may be formed from SiON. Because there is a greater band offset between an SiO₂ intervening insulation layer 210 and the SiC layer 110 compared to between an Al₂O₃ channel depletion layer 120 and the SiC layer 110, providing the SiO₂ intervening insulation layer 210 between the Al₂O₃ channel depletion layer 120 and the channel region 116 may decrease the leakage current between the channel region 116 and the gate contact 130. The SiO₂ intervening insulation layer 210 may additionally or alternatively improve the electron mobility of the channel region 116 compared to forming the Al₂O₃ channel depletion layer 120 directly on the channel region 116 which may result in charge traps and/or other undesirable characteristics that may decrease electron mobility along the interface therebetween.

As used herein, “p-type”, “p+”, “n-type”, and “n+” refer to regions that are defined by higher carrier concentrations than are present in adjacent or other regions of the same or another layer or substrate. Although various embodiments are described herein in the context of n-type MISFETs that include n-type channel, n+ source, and n+ drain regions on a semiconductor layer, according to some other embodiments p-type MISFETs structures are provided that include p-type channel, p+ source, and p+ drain regions on a semiconductor layer. For p-type MISFETs, the dielectric channel depletion layer 120 is configured to provide a fixed positive charge along a surface facing a channel region that depletes charge carriers (e.g., holes) from at least an adjacent portion of the channel region 116 when a zero voltage potential is present between the gate contact 130 and the source region 112.

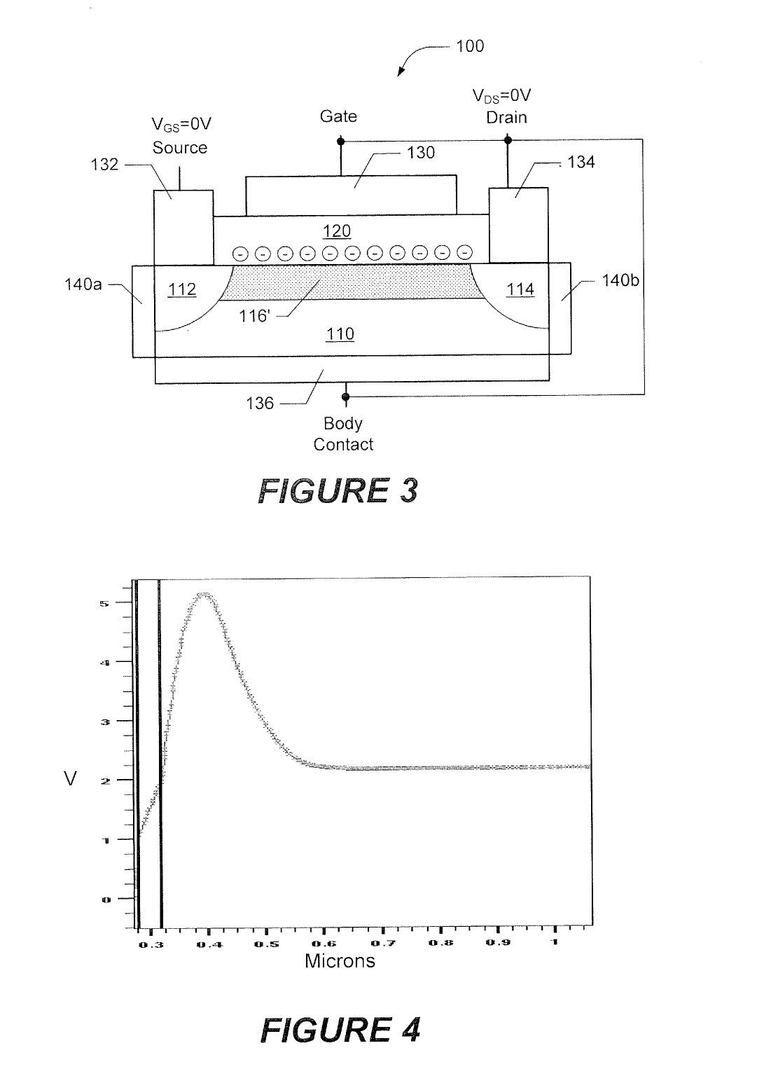

Various exemplary operational characteristics that may be provided when the MISFET 100 shown in FIG. 1 is in an off state, in a partially-on state, and in a fully-on state will now be described with reference to FIGS. 3-9. In FIGS. 3-9, the MISFIT 100 has an Al₂O₃ channel depletion layer 120 with a thickness of 0.5 μm and a fixed charge of −6×10¹² cm⁻², and a channel region 120 with an n-type doping concentration of 6.5×10¹⁷ cm⁻³ and a thickness of 0.1 μm (resulting in a doping and thickness product of 6.5×10¹² cm⁻²).

FIG. 3 is a cross-sectional view of the MISFET 100 of FIG. 1 when zero voltage is present between the gate contact 130 and the source contact 132, and the gate contact 130, the drain contact 134, and the body contact 136 are electrically connected. FIG. 4 is a graph of a potential that may occur with depth across the doped channel region of the MISFET of FIG. 3. Referring to FIGS. 3 and 4, it is observed that the fixed negative charge in the Al₂O₃ channel depletion layer 120 causes the channel region 116 to be effectively depleted of charge carriers through 0.5 μm (indicated by the depletion region 116′) and, therefore, pinched off. Consequently, very little (if any) current should flow through the drain contact 134.

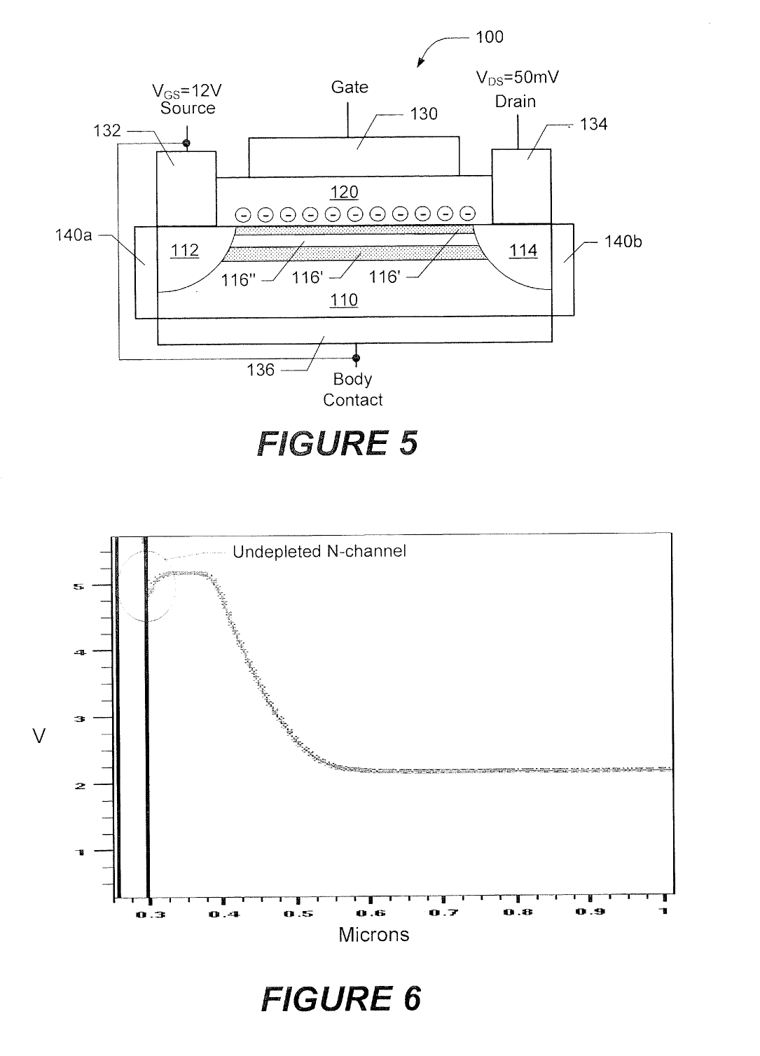

FIG. 5 is a cross-sectional view of the MISFET 100 of FIG. 1 when 12V (the threshold voltage for the MISFET 100) is applied between the gate contact 130 and the source contact 132, and when the source contact 132 and the body contact 136 are electrically connected. FIG. 6 is a graph of a potential that may occur with depth across the doped channel region of the MISFET of FIG. 5. Referring to FIGS. 5 and 6, it is observed that applying V_{GS}=12V causes the depletion region 116′ to recede from a central region of the channel region 116 (between about 0.32 μm and about 0.38 μm in FIG. 6) because many of the negative charges provided by the Al₂O₃ channel depletion layer 120 are mirrored in the gate electrode 130, which thereby forms a centrally located undepleted charge carrier region 116″. The depletion region 116′ along the bottom of the channel region 116 (between about 0.38 μm and about 0.5 μm in FIG. 6) remains because the voltage between the source contact 132 and the body contact 136 did not change from the configuration shown in FIG. 3, and the depletion region 116′ along the top of the channel region 116 (between about 0 μm and about 0.32 μm in FIG. 6) remains because of the negative charge provided by the Al₂O₃ channel depletion layer 120. Consequently, a current can flow through the centrally located undepleted charge carrier region 116″ to the drain contact 134.

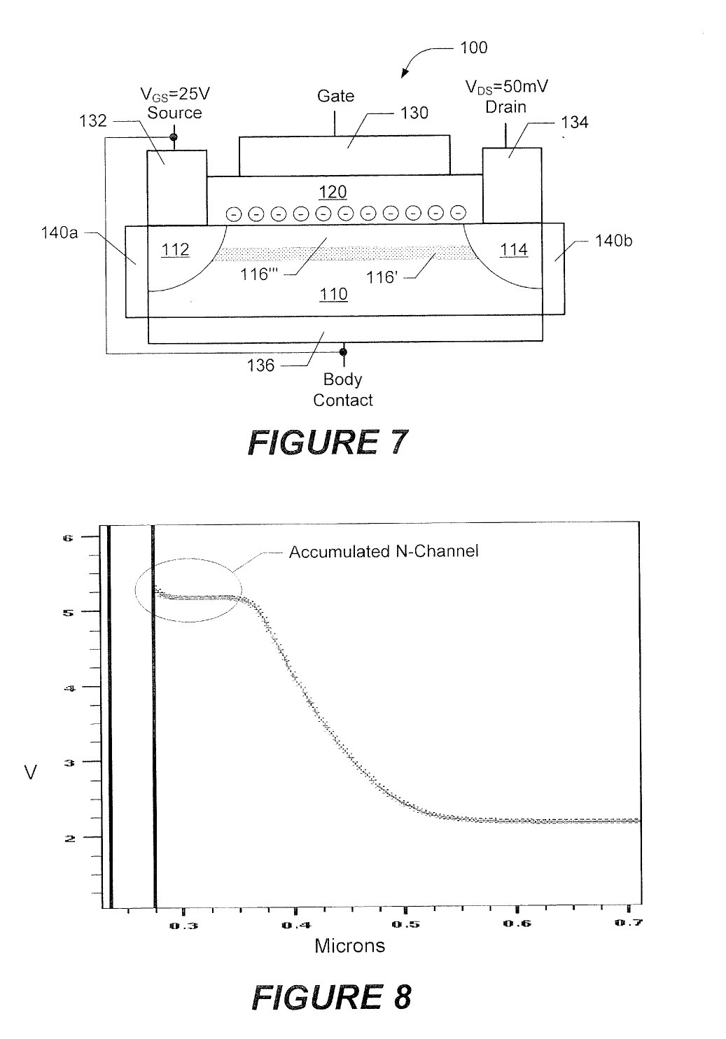

FIG. 7 is a cross-sectional view of the MISFET 100 of FIG. 1 when 25V is applied between the gate contact 130 and the source contact 132, and when the source contact 132 and the body contact 136 are electrically connected. FIG. 8 is a graph of a potential that may occur with depth across the doped channel region of the MISFET of FIG. 7. Referring to FIGS. 7 and 8, it is observed that applying V_{GS}=25 V causes the undepleted charge carrier region 116′″ to extend upward to the surface of the channel region 116 because many more of the negative charges provided by the Al₂O₃ channel depletion layer 120 are now mirrored in the gate electrode 130. Consequently, a much higher current can flow through undepleted charge carrier region 116″ to the drain contact 134.

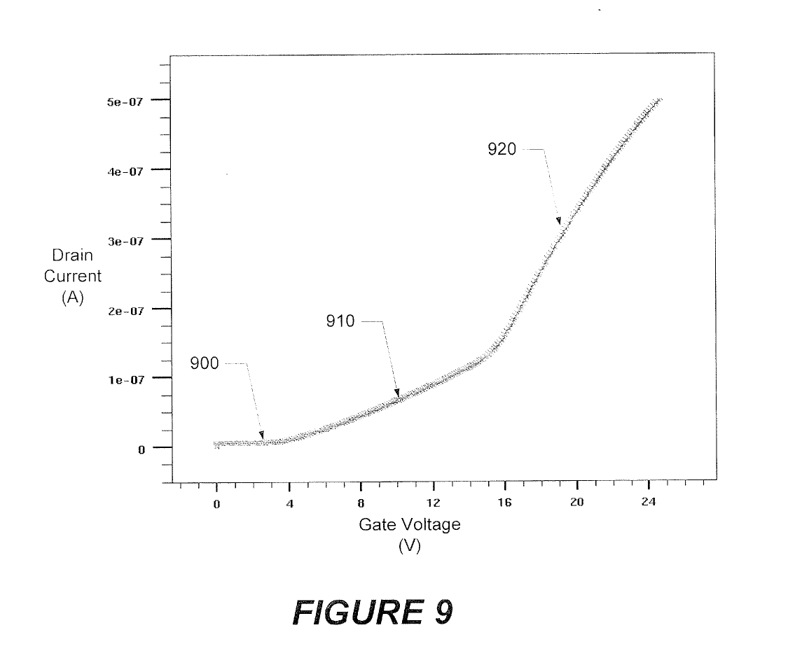

FIG. 9 is a graph of the drain current versus gate voltage operational characteristics that may be provided by the MISFET 100 of FIG. 1. Referring to FIG. 9, it is observed that when the MISFET 100 is configured as shown in FIG. 3, the drain current is essentially zero (line segment 900) with the channel region 116 pinched-off until the gate voltage reaches about 4V. As the gate voltage rises above 4V the drain current through the central undepleted charge carrier region 116″ (e.g., shown in FIG. 5) gradually increases (line segment 910) until the gate voltage reaches about 16V. As the gate voltage rises above 16V the drain current through the undepleted charge carrier region 116″ (e.g., shown in FIG. 7) rapidly rises (line segment 920).

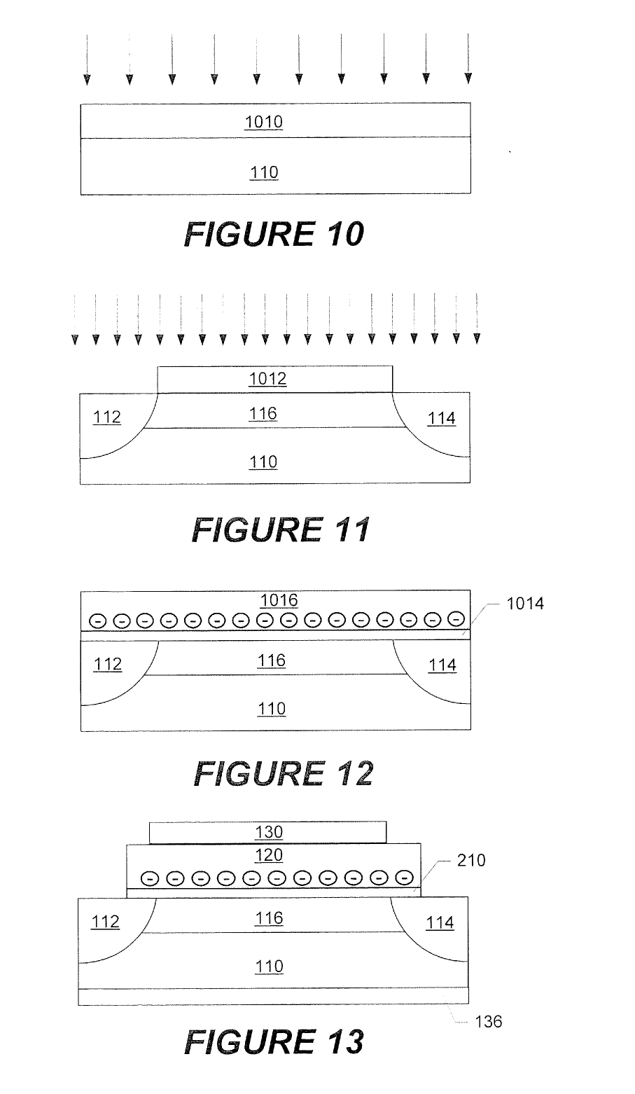

FIGS. 10-13 are a sequence of cross-sectional views of processes for fabricating the MISFET of FIG. 2 in accordance with some embodiments of the present invention. Referring to FIG. 10, an SiC layer 110 is provided. A n-type layer 1010 is formed in the SiC layer 110 by implanting, for example, nitrogen and/or phosphorous atoms. The n-type layer 1010 forms the channel region 116 by implanted n-type dopants at a concentration from about 1×10¹⁶ cm⁻³to about 1×10¹⁸ cm⁻³ and to a depth from about 0.1 μm to about 0.5×10⁻⁵ μm in the SiC layer 110.

Referring to FIG. 11, a mask pattern 1012 is formed over a portion of the n-type layer 1010 that will become the channel region 116. Further n-type dopants are implanted into the SiC semiconductor layer 110 to form the n+ source region 112 and the n+ drain region 114 with an n-type dopant concentration from about 1×10¹⁹ cm⁻³ to about 1×10²¹ cm⁻³. The implanted dopants are then annealed at a temperature from about 1300° C. to about 2000° C. to form the channel region 116, the source region 112, and the drain region 114. The mask pattern 1012 can be removed before or after annealing.

The depth and concentration of the dopants that are implanted into the channel region 116 depends upon the quantity of fixed negative charge that will be provided by the subsequently formed dielectric channel depletion layer 120. As explained above, a product of the doping concentration and thickness of the channel region 116 should be equal to or less than the amount of negative fixed charge provided by the dielectric channel depletion layer 120.

Referring to FIG. 12, an insulation layer 1014 is formed across the SiC layer 110, such as by thermally oxidizing the SiC layer 110 to form a layer of SiO₂. As explained above, the insulation layer 1014 should be very thin, such as less than 100 Å, so that the charge provided by the subsequently formed dielectric channel depletion layer 120 is closely located to the channel region 116 to enable depletion of charge carriers from a deeper region of the channel region 116. A dielectric layer 1016 of a material, such as Al₂O₃ or HfO₂, that provides a fixed negative charge is formed (e.g., by atomic layer deposition and/or by chemical vapor deposition) across the insulation layer 1014.

After formation of the dielectric layer 1016, subsequent process steps should be performed below a crystallization temperature of the dielectric layer 1016 to avoid increasing leakage current between the gate contact 130 and the channel region 116 because of crystallization of the dielectric layer 1016. For example, when the dielectric layer 1016 is formed from Al₂O₃, subsequent process steps should be performed below about 850° C. to avoid crystallization of the Al₂O₃.

Referring to FIG. 13, the insulation layer 1014 and the dielectric layer 1016 are patterned, such as by a wet or dry etch process, to form the intervening insulation layer 210 and the dielectric channel depletion layer 1016, respectively. A gate contact 130, a source contract 132, and a drain contact 134 are formed by, for example, depositing and then patterning one or more layers of nickel or other suitable metal on the dielectric channel depletion layer 1016. A body contact 136 is formed on an opposite surface of the SiC layer 110 by, for example, depositing a layer of nickel or other suitable metal.

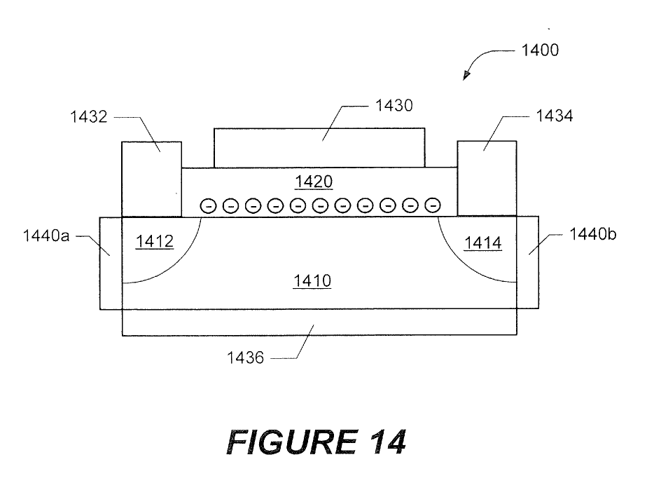

FIG. 14 is a cross-sectional view of another embodiment of a MISFET 1400 that is configured in accordance with some embodiments of the present invention. Referring to FIG. 14, the MISFET 1400 includes a SiC semiconductor layer 1410, which may be a high purity semi-insulating (HPSI) 4H-SiC substrate. A source region 1412 and a drain region 1414 are spaced apart along a surface of the semiconductor layer 1410. A gate contact 1430 is aligned over a channel region between the source region 1412 and the drain region 1414. A dielectric channel depletion layer 1420 separates the gate contact 1430 from the semiconductor layer 1410. A source contact 1432 contacts the source region 1412 and a drain contact 1434 contacts the drain region 1414. A body contact 1436 is on an opposite surface of the semiconductor layer 1410 from the gate contact 1430. The contacts 1432, 1434. and 1436 may include nickel or other suitable metal. The MISFET 1400 may be isolated from adjacent devices on the semiconductor layer 1410 by isolation regions 1440a-b (e.g., shallow trench isolation regions).

The depletion layer 1420 provides a net fixed charge (e.g. the negative charge symbols in FIG. 1) that has the same polarity as majority charge carriers (e.g., electrons) in the channel region between the source and draft regions 1412 and 1414, and which, thereby, depletes the majority carriers from at least an adjacent portion of the channel region when the V_{GS} is zero. Because the fixed charge in the depletion layer 1420 forces charge carriers away from the adjacent channel region, the threshold voltage of the MISFET 1400 may be increased.

The depletion layer 1420 may be formed from a material, such as Al₂O₃ or HfO₂, that provides a fixed negative charge that depletes electrons by forcing them away from at least an adjacent portion of a n-type doped channel region for V_{GS} less than the threshold voltage. For example, a layer of Al₂O₃ may be used as the depletion layer 1420 to provide a negative fixed charge density of −6×10¹² cm⁻². Using a layer of Al₂O₃ as the depletion layer 1420 may also reduce leakage current between the channel region and the gate contact 1430 because of the higher band gap difference (band offset) between the Al₂O₃ layer and the semiconductor layer 1410 compared to using another dielectric material having a negative fixed charge, such as HfO₂, having a lower band gap than Al₂O₃. The choice of material and thickness of the depletion layer 1420 should be selected to generate a net charge per unit area that is at least as high as a net charge generated by dopants in an adjacent unit area of the channel region, such as described above with regard to Equation 1.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A metal-insulator-semiconductor field-effect transistor (MISFET) comprising:
a semiconductor layer having source and drain regions of a first conductivity type spaced apart therein;
a channel region of the first conductivity type that extends between the source and drain regions in the semiconductor layer;
a gate contact on the channel region; and
a dielectric channel depletion layer between the gate contact and the channel region, the dielectric channel depletion layer providing a net charge having the same polarity as the first conductivity type charge carriers.

2. The MISFET of claim 1, wherein:
the dielectric channel depletion layer comprises a material that depletes the first conductivity type charge carriers from an adjacent portion of the channel region when the voltage potential between the gate contact and the source region is zero.

3. The MISFET of claim 1, wherein:
the semiconductor layer comprises silicon carbide SiC;
the channel region is an n-type region and the source and drain regions are n+ regions; and
the dielectric channel depletion layer comprises Al₂O₃.

4. The MISFET of claim 1, wherein:
the semiconductor layer comprises silicon carbide SiC;
the channel region is a n-type region and the source and drain regions are n+ regions; and
the dielectric channel depletion layer comprises HfO₂.

5. The MISFET of claim 1, wherein a material and thickness of the dielectric channel depletion layer are configured to generate a net charge per unit area that is at least as high as a net charge generated by the first conductivity type charge carriers in the channel region.

6. The MISFET of claim 5, wherein:
the net charge provided by the dielectric channel depletion layer is at least as high as a product of a concentration of first conductivity type dopants in the channel region and a thickness of the channel region.

7. The MISFET of claim 1, wherein the channel region has a n-type dopant concentration of from about 1×10¹⁶ cm⁻³ to about 1×10¹⁸ cm⁻³ and a thickness from about 0.1 μm to about 0.5×10⁻⁵ μm.

8. The MISFET of claim 7, wherein a combination of a material and thickness of the dielectric channel depletion layer generates a charge density from about −1×10¹¹ cm⁻²to about −5×10³ cm⁻².

9. The MISFET of claim 7, wherein the source and drain regions each have a n-type dopant concentration from about 1×10¹⁹ cm to about 1×10²¹ cm ⁻³. I

10. The MISFET of claim 1, further comprising an intervening insulation layer between the dielectric channel depletion layer and the channel region.

11. The MISFET of claim 10, wherein the intervening insulation layer comprises a layer of SiO₂ and/or SiON with a thickness less than 100 Å.

12. A metal-insulator-semiconductor field-effect transistor (MISFET) comprising:
a n+ a source region and a n+ drain region spaced apart in a silicon carbide SiC layer;
a n-type channel region that extends between the source and drain regions;
a gate contact on the channel region; and
an Al₂O₃ layer between the gate contact and the channel region that provides a net negative charge that depletes n-type charge carriers from at least an adjacent portion of the channel region when the voltage potential between the gate contact and the source region is zero.

13. The MISFET of claim 12, wherein the channel region has a n-type dopant concentration from about 1×10¹⁶ cm⁻³ to about 1×10¹⁸ cm⁻³ and a thickness from about 0.1 μm to about 0.5×10⁻⁵ μm.

14. The MISFET of claim 13, wherein the source and drain regions each have a n-type dopant concentration from about 1×10¹⁹ cm⁻³ to about 1×10²¹ cm⁻³.

15. The MISFET of claim 12, further comprising a layer of SiO₂ and/or SiON with a thickness less than 100Å between the Al₂O₃ layer and the channel region.

16. A method of fabricating a metal-insulator-semiconductor field-effect transistor (MISFET), the method comprising:
providing spaced apart source and drain regions of a first conductivity type in a semiconductor layer;
providing a channel region with first conductivity type impurity atoms that extends between the spaced apart source and drain regions in the semiconductor layer;
forming a dielectric channel depletion layer on the channel region; and
forming a gate contact on the dielectric channel depletion layer over the channel region, wherein the dielectric channel depletion layer provides a net charge having the same polarity as the first conductivity type charge carriers.

17. The method of claim 16, wherein the channel region is formed by implanting n-type dopants at a concentration from about 1×10¹⁶ cm⁻³to about 1×10¹⁸ cm⁻³ and to a depth of from about 0.1 μm to about 0.5×10⁻⁵ μm in the semiconductor layer.

18. The method of claim 16, further comprising:
annealing the first conductivity type impurity atoms implanted to form the channel region at a temperature from about 1300° C. to about 2000° C. before forming the dielectric channel depletion layer on the channel region.

19. The method of claim 16, wherein:
the source and drain regions are n+ regions in a silicon carbide SiC layer;
the channel region is formed as an n-type region; and
forming the dielectric channel depletion layer comprises depositing Al₂O₃ on the channel region of the SiC layer.

20. The method of claim 16, further comprising forming a layer of SiO₂ and/or SiON with a thickness less than 100Å on the channel region before forming the dielectric channel depletion layer, wherein the layer of SiO₂ and/or SiON is between the dielectric channel depletion layer and the channel region.

21. A metal-insulator-semiconductor field-effect transistor (MISFET) comprising:
a silicon carbide SiC layer having source and drain regions of a first conductivity type spaced apart therein;
a gate contact on a channel region of the SiC layer between the source and drain regions; and
a depletion layer between the gate contact and the SiC layer, the depletion layer having a net charge that is the same polarity as the first conductivity type charge carriers.

22. The MISFET of claim 21, wherein:
the depletion layer comprises a material having a fixed charge that depletes the first conductivity type charge carriers from an adjacent portion of the channel region when a voltage potential between the gate contact and the source region is zero.

23. The MISFET of claim 22, wherein a material and thickness of the depletion layer are configured to generate a net charge per unit area that is at least as high as a net charge generated by the first conductivity type charge carriers in the channel region when a voltage potential between the gate contact and the source region is zero.
